(19) United States
(12) Patent Application Publication
(10) Pub. No.: US 2024/0306323 A1
(43) Pub. Date: Sep. 12, 2024

(54) VENT ASSEMBLY

(71) Applicant: W. L. Gore & Associates G.K., Tokyo (JP)

(72) Inventor: Kazuhiro Minami, Tokyo (JP)

(21) Appl. No.: 18/579,788

(22) PCT Filed: Jul. 16, 2021
(86) PCT No.: PCT/IB2021/056457

§ 371 Date: Jan. 16, 2024

(51) Int. Cl. H05K 5/02; H04R 1/02; H04R 1/08

(52) U.S. Cl. CPC H05K 5/0214; H04R 1/023; H04R 1/086

(57) ABSTRACT

There is provided a vent assembly comprising a first connecting layer, a spacer, and a protective element, the first connecting layer comprises a first aperture, wherein the spacer comprises a spacer aperture and the protective element is located within the spacer aperture and occludes the first aperture, and wherein the spacer and protective element are contacted by the first connecting layer.

### CROSS-REFERENCE TO RELATED APPLICATION

This application is a national phase application of PCT Application No. PCT/IB2021/056457, internationally filed on Jul. 16, 2021, which is herein incorporated by reference in its entirety for all purposes.

### FIELD

The disclosure relates to vents for housings, specifically to vents for housings for electrical or electronic devices.

### BACKGROUND

Vents and vent assemblies can be used to reduce pressure fluctuations within electronic housings, as well as to control humidity. Such vents and vent devices must also prevent ingress of dirt and other contaminants, and to also prevent the ingress of water.

Further, vents and vent assemblies are often used to allow sound generated by one or more speakers within the housing to pass out of the housing through the vent with minimal attenuation. Conversely, vent and vent assemblies are also used to allow sound generated external from a housing to pass into the housing through the vent to an internal microphone or similar with minimal sound attenuation.

Typical vent assemblies often include a water-vapor permeable, liquid water resistant or water proof membrane fixed to a support. The support is often mounted to span an aperture within the housing to thereby seal the aperture but to allow the pressure within the housing to be equalised and to allow sound to more readily be heard.

Other vent assemblies include a mesh of water resistant fibers. The mesh typically has a greater sound permeability than water resistant membranes and so generally results in a reduced attenuation of sound passing across the mesh.

Such meshes are often sandwiched between adhesive layers to attach the vent assembly to the housing and to attach any further layers to the mesh. However, such sandwiched constructions can suffer from water leakage through the periphery of the mesh.

Further, these vent assemblies can also suffer from delamination of one or more adhesive layers from the mesh resulting in failure of the vent assembly and ingress of water and/or dirt into the housing, or can be problematic during assembly of the vent assembly to a housing.

Accordingly, there remains a need for improved venting assemblies for use with electronics housings.

Therefore, at least some embodiments are directed to the provision of improved vent assemblies that solve at least one of these problems.

### SUMMARY

According to a first aspect there is provided a vent assembly comprising a first connecting layer, a spacer, and a protective element, the first connecting layer comprises a first aperture, wherein the spacer comprises a spacer aperture and the protective element is located within the spacer aperture and occludes the first aperture, and wherein the spacer and protective element are contacted by the first connecting layer.

The inventor has found that the provision of a vent assembly including a spacer surrounding a protective element results in a more durable vent assembly that is more readily handled during application of the vent assembly to a housing and provides resistance to folding or wrinkling of the vent assembly.

The protective element may be water resistant. The protective element may be waterproof. The protective element may be gas-permeable. The protective element may be water-vapor permeable. Accordingly, the protective element may prevent or at least reduce the ingress of water and particles of dirt into a housing to which the vent assembly is fixed and allows water vapor and air to pass into and out of the housing. Therefore, the protective element allows the pressure within a housing to be equalised across the vent assembly.

The protective element may comprise a mesh layer. The mesh layer may comprise a woven material. The mesh layer may comprise a weave of fibers. The mesh layer may comprise a non-woven material. The mesh layer may comprise a polymer fiber. The polymer fiber may comprise polyethylene (PE), polyethylene terephthalate (PET), or a fluoropolymer such as polytetrafluoroethylene (PTFE) or fluorinated ethylene propylene (FEP), for example. The polymer fiber may comprise PET.

The surface of the mesh layer may be hydrophilic or comprise a hydrophilic coating. Accordingly, the surface of the mesh layer may be readily wetted by water. The surface of the mesh may be hydrophobic or comprise a hydrophobic coating. Accordingly, the surface of the mesh layer may resist being wetted by water.

The protective element may comprise a membrane. The membrane may be a porous membrane. The pores of the porous membrane may be dimensioned to maximise the passage of air and water-vapor through the porous membrane but to prevent passage of liquid water and particles of dirt across the porous membrane.

The membrane may have been expanded. The membrane may have been biaxially expanded. The membrane may comprise a node and fibril structure. Accordingly, the membrane may be described as a fibrillated membrane. The membrane may include voids within the node and fibril structure. For example, the membrane may comprise expanded polytetrafluoroethylene (ePTFE).

The protective element may comprise a mesh and a membrane. The membrane may be laminated to the mesh. The membrane may be directly bonded onto the mesh. The mesh may provide a physical support to the membrane. The mesh may minimise deformation of the membrane under stress.

The protective element may comprise a water resistant coating. The water resistant coating may be on a first surface of the protective element. The protective element may comprise a water proof coating. The water proof coating may be on a first surface of the protective element. The first surface may face the exterior of a housing when the vent assembly is mounted to a housing.

The protective element may have a thickness of from about 1 μm to about 2000 μm. The protective element may have a thickness of from about 5 μm to about 1000 μm. The protective element may have a thickness of from about 5 μm to about 500 μm. The protective element may have a thickness of from about 10 μm to about 200 μm. The protective element may have a thickness of from about 10 μm to about 150 μm. The protective element may have a thickness of from about 10 μm to about 100 μm. The protective element may have a thickness of from about 30 μm to about 200 μm. The protective element may have a thickness of from about 50 μm to about 200 μm. The protective element may have a thickness of from about 70 μm to about 200 μm. The protective element may have a thickness of from about 100 μm to about 200 μm. The protective element may have a thickness of from about 10 μm to about 70 μm. The protective element may have a thickness of from about 30 μm to about 70 μm. The protective element may have a thickness of from about 50 μm to about 70 μm. The protective element may have a thickness of from about 50 μm to about 60 μm.

It will be appreciated that the thickness of the protective element will be dependent on the nature of the protective element. In embodiments where the protective element is a mesh, the protective element may have a thickness of about 50 μm to about 500 μm, about 50 μm to about 400 μm, about 50 μm to about 300 μm, about 50 μm to about 200 μm or about 50 μm to about 100 μm, for example. In embodiments where the protective element is a membrane, the protective element may have a thickness of about 0.5 μm to about 70 μm, about 1 μm to about 70 μm, about 1 μm to about 50 μm, about 1 μm to about 30 μm, about 1 μm to about 20 μm, or about 1 μm to about 10 μm, for example. In embodiments where the protective element comprises a membrane and a mesh, the protective element may have a thickness corresponding to the sum of the thickness of the membrane and the mesh. For example, the protective element may have a thickness of about 50 μm to about 500 μm, about 50 μm to about 400 μm, about 50 μm to about 350 μm, or about 50 μm to about 200 μm. The protective element may have a thickness of about 75 μm to about 500 μm, about 75 μm to about 400 μm, about 75 μm to about 350 μm, or about 75 μm to about 300 μm.

The first connecting layer may fix the vent assembly together. The first connecting layer may provide a substrate that allows the spacer and protective element to be fixed relative to one another within the vent assembly. The spacer and/or the protective element may be welded to the first connecting layer. The spacer and/or the protective element may be adhered to the first connecting layer. Accordingly, the first connecting layer may be a first adhesive layer.

The spacer may comprise an adhesive. Accordingly, the spacer and the first connecting layer may connect the parts of the vent assembly together.

In some embodiments, the vent assembly may comprise a second connecting layer. The second connecting layer may comprise a second aperture. The protective element and the spacer may be located between the first connecting layer and the second connecting layer. The protective element may occlude the second aperture. The second connecting layer may provide a substrate that allows the spacer and protective element to be fixed relative to one another within the vent assembly. The spacer and/or protective element may be welded to the second connecting layer. The spacer and/or the protective element may be adhered to the second connecting layer. Accordingly, the second connecting layer may be a second adhesive layer.

In some embodiments, the first connecting layer and the second connecting layer may be a first adhesive layer and a second adhesive layer.

The first adhesive layer may comprise adhesive on a first side. The first adhesive layer may comprise adhesive on a second side. The first adhesive layer may comprise adhesive on a first side and on a second side. Accordingly, the first adhesive layer may be described as “single-sided” (i.e. it has adhesive on one side only) or “double-sided” (i.e. it has adhesive on both sides).

Known vent assemblies where connecting layers are solely adhered to a protective element often suffer from delamination where the connecting layer can be peeled or otherwise come away from the protective element. For example, where the protective element is water resistant the adhesive of the connecting layer may not adhere to the protective element well. In other examples where the protective element comprises a mesh layer, the adhesive of the connecting layer may adhere to the fibers of the mesh poorly due to the relatively low surface area of the mesh.

A vent assembly according to the present aspect may adhere the first connecting layer to both the spacer and the protective element. Accordingly, the vent assembly is more resistant to delamination as the adhesion is not solely dependent on the adhesion between the protective element and the or each connecting layer.

In some embodiments the protective element may be positioned substantially within the center of the spacer aperture. The protective element may be dimensioned such that it is smaller than the spacer aperture. The protective element may be located within the spacer aperture such that there is a space between the periphery of the protective element and the spacer. Accordingly, in some embodiments the protective element may not contact the spacer. Alternatively, in some embodiments, the protective element may contact the spacer and there may not be a space between the periphery of the protective element and the spacer.

The spacer may comprise a polymer material. The spacer may comprise a non-porous polymer material. The spacer may comprise a micro-porous polymer material. The spacer may comprise a water resistant polymer material. For example, the spacer may comprise polyethylene (PE), polyethylene terephthalate (PET), or a fluoropolymer such as polytetrafluoroethylene (PTFE) or fluorinated ethylene propylene(FEP), for example. In some embodiments the spacer may comprise PE or PET, preferably PET.

The spacer may be configured such that the major surfaces of the spacer are in contact with the first adhesive layer and the second adhesive layer. The spacer may comprise a substantially continuous surface adjacent to the first adhesive layer and/or adjacent to the second layer such that the surfaces of the spacer maximise the surface area presented to the first adhesive layer and the second adhesive layer for adhesion.

The spacer may have a thickness of from about 1 μm to about 2000 μm. The spacer may have a thickness of from about 5 μm to about 1000 μm. The spacer may have a thickness of from about 5 μm to about 500 μm. The spacer may have a thickness of from about 10 μm to about 200 μm. The spacer may have a thickness of from about 10 μm to about 150 μm. The spacer may have a thickness of from about 10 μm to about 100 μm. The spacer may have a thickness of from about 30 μm to about 200 μm. The spacer may have a thickness of from about 50 μm to about 200 μm. The spacer may have a thickness of from about 70 μm to about 200 μm. The spacer may have a thickness of from about 100 μm to about 200 μm. The spacer may have a thickness of from about 10 μm to about 70 μm. The spacer may have a thickness of from about 20 μm to about 70 μm. The spacer may have a thickness of from about 20 μm to about 60 μm. For example, the spacer may have a thickness of about 20 μm, 25 μm, 30 μm, 35 μm, 40 μm, 45 μm, 50 μm, 55 μm or 60 μm or values therebetween.

The spacer and protective element may be dimensioned to provide a substantially level surface to which the first connecting layer and, in embodiments comprising a second connecting layer, to which the second connecting layer are adhered. The spacer and protective element may be the same thickness or substantially the same thickness. The first connecting layer and the second connecting layer may be substantially planar across at least the spacer and the protective element. Accordingly, the first connecting layer and the second connecting layer do not comprise a bend that may result if the spacer has a significantly different thickness compared to the protective layer or for prior vent assemblies that do not comprise a spacer and the connecting layers extend beyond the protective element.

As used herein, the term “substantially level” refers to a surface that is level or level within measuring tolerances, or to minimise the deformation of the surface that leads to delamination of the vent assembly.

As used herein, the term “substantially the same thickness” refers to the spacer and the protective element having a thickness that presents a substantially level surface to the at least first layer.

Accordingly, the spacer and protective element may have a thickness of from about 1 μm to about 2000 μm. The spacer and protective element may have a thickness of from about 5 μm to about 1000 μm. The spacer and protective element may have a thickness of from about 5 μm to about 500 μm. The spacer and protective element may have a thickness of from about 10 μm to about 200 μm. The spacer and protective element may have a thickness of from about 10 μm to about 150 μm. The spacer and protective element may have a thickness of from about 10 μm to about 100 μm. The spacer and protective element may have a thickness of from about 30 μm to about 200 μm. The spacer and protective element may have a thickness of from about 50 μm to about 200 μm. The spacer and protective element may have a thickness of from about 70 μm to about 200 μm. The spacer and protective element may have a thickness of from about 100 μm to about 200 μm. The spacer and protective element may have a thickness of from about 10 μm to about 70 μm. The spacer and protective element may have a thickness of from about 30 μm to about 70 μm. The spacer and protective element may have a thickness of from about 50 μm to about 70 μm. The spacer and protective element may have a thickness of from about 50 μm to about 60 μm.

In some embodiments the spacer may have a thickness that is less than the thickness of the protective element. Accordingly, the spacer may be thinner than the protective element. The spacer may have a thickness that is less than 80% the thickness of the protective element. The spacer may have a thickness that is less than 70% the thickness of the protective element. The spacer may have a thickness that is less than 60% the thickness of the protective element. The spacer may have a thickness that is less than 50% the thickness of the protective element. The spacer may have a thickness that is less than 40% the thickness of the protective element. The spacer may have a thickness that is less than 30% the thickness of the protective element.

The spacer may have a thickness that is from 30% to 100% the thickness of the protective element. The spacer may have a thickness that is from 30% to 70% the thickness of the protective element. The spacer may have a thickness that is from 30% to 50% the thickness of the protective element.

In some embodiments the spacer may have a thickness that is greater than the thickness of the protective element. Accordingly, the spacer may be thicker than the protective element. The spacer may have a thickness that is more than 110% the thickness of the protective element. The spacer may have a thickness that is more than 120% the thickness of the protective element. The spacer may have a thickness that is more than 130% the thickness of the protective element. The spacer may have a thickness that is more than 140% the thickness of the protective element. The spacer may have a thickness that is more than 150% the thickness of the protective element.

The spacer may have a thickness that is from 110% to 200% the thickness of the protective element. The spacer may have a thickness that is from 110% to 150% the thickness of the protective element. The spacer may have a thickness that is from 110% to 130% the thickness of the protective element.

For the avoidance of doubt, a spacer that is 50% the thickness of the protective element has a thickness that is half the thickness of the protective element. A spacer that is 200% the thickness of the protective element has a thickness that is twice the thickness of the protective element.

Typically, in embodiments comprising a first connecting layer and a second connecting layer, the spacer may not be an adhesive layer. The spacer may not comprise an adhesive prior to assembly of the device.

The vent assembly may further comprise a membrane connected to the first connecting layer. The vent assembly may further comprise a support to which a membrane is directly or indirectly attached.

In some embodiments where the protective element comprises a mesh layer, the vent assembly may comprise a mesh layer within a spacer aperture and a membrane. The membrane may be water resistant. The membrane may be water proof. The membrane may be porous. The membrane may be micro-porous. The membrane may be water resistant and water-vapor permeable. The membrane may be water proof and water-vapor permeable. The membrane may comprise PTFE or ePTFE, for example.

The vent assembly may further comprise a cover. The cover may comprise a cover aperture. The cover aperture may be coaxial with the first aperture and/or the second aperture. The cover may be adhered to the first connecting layer. The cover may be adhered to the second connecting layer. The cover may be adhered directly to the spacer and the protective element. The cover may be a mechanical strengthening layer. The cover may be a cushioning layer to absorb impact or compression applied to the vent assembly.

The first aperture and the second aperture may at least partially overlap. The first aperture and the second aperture may be co-axial. Accordingly, the first aperture and the second aperture may form a through hole through the vent assembly and the protective element may occlude the through hole.

In embodiments where the vent assembly comprises a membrane, a protective element, a spacer and a cover, the vent assembly may comprise a third connecting layer. The third connecting layer may comprise a third aperture. The first connecting layer may adhere the cover to the protective element and the spacer. The second connecting layer adheres the protective element and the spacer to the membrane and the third connecting layer is configured to adhere the vent assembly to a housing.

In at least some embodiments the first connecting layer, the second connecting layer and, in embodiments comprising a third connecting layer, the third connecting layer may be interchangeable.

Accordingly, it will be understood that reference to “first connecting layer”, “second connecting layer” and “third connecting layer” merely is used to differentiate connecting layers within an embodiment of a vent assembly and is not intended to imply necessarily that the connecting layers are strictly ordered within embodiments.

In a second aspect there is provided an electronic device comprising a housing and vent assembly according to the first aspect, wherein the housing comprises at least one aperture and the vent assembly covers the at least one aperture.

The vent assembly may be connected to the housing via the first connecting layer. The vent assembly may be connected to the housing via the second connecting later in embodiments where the vent assembly comprises a second connecting layer.

In embodiments where the vent assembly comprises a membrane the membrane may face the exterior of the housing. The mesh may face the exterior of the housing.

According to a third aspect there is provided an array of vent assemblies comprising a plurality of vent assemblies according to the first aspect mounted on a release paper.

The release paper may be configured to retain each vent assembly of the plurality of vent assemblies and to readily allow a vent assembly to be individually removed from the release paper to allow the vent assembly to be mounted onto a housing.

### BRIEF DESCRIPTION OF THE FIGURES

Embodiments of the present invention will now be described, by way of non-limiting example, with reference to the accompanying drawings.

FIG. 1: An example of a prior venting device A) in an exploded view and B) in a cross section;

FIG. 2: An example vent assembly according to the disclosure A) in an exploded view and B) in a cross section;

FIG. 3: A cross section of an example vent assembly mounted on a housing according to an embodiment;

FIG. 4: A cross section of an example vent assembly mounted on a housing according to an embodiment;

FIG. 5: A cross section of a release paper comprising three vent assemblies according to an embodiment;

FIG. 6: A cross section of an example vent assembly mounted on a housing according to an embodiment;

FIG. 7: A cross section of an example vent assembly mounted on a housing according to an embodiment;

FIG. 8: A cross section of an example vent assembly mounted on a housing according to an embodiment; and

FIG. 9: A cross section of an example vent assembly mounted on a housing according to prior device.

### DETAILED DESCRIPTION

While the making and using of various embodiments of the present disclosure are discussed in detail below, it should be appreciated that the present disclosure provides many applicable inventive concepts that can be embodied in a wide variety of specific contexts. The specific embodiments discussed herein are merely illustrative of specific ways to make and use the invention and do not delimit the scope of the disclosure.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

### EXAMPLES

### Comparative Example 1

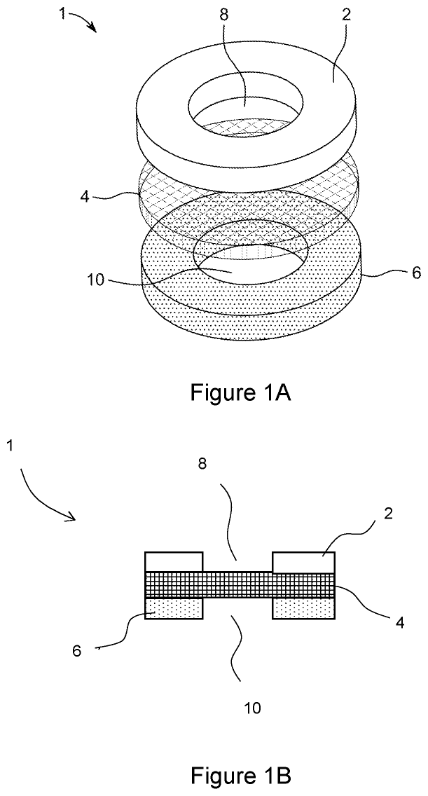

With reference to FIG. 1A and FIG. 1B a typical venting device 1 in the art comprises a first adhesive layer 2, a mesh 4 (acting as a protective element) and a second adhesive layer 6. The first adhesive layer 2 comprises a first aperture 8 and the second adhesive layer 6 comprises a second aperture 10. The first aperture 8 and the second aperture 10 form a through hole. The mesh 4 is sandwiched between the first adhesive layer 2 and the second adhesive layer 6 such that it occludes the through hole and extends to the periphery of the first adhesive layer 2 and the second adhesive layer 6.

### Example 1

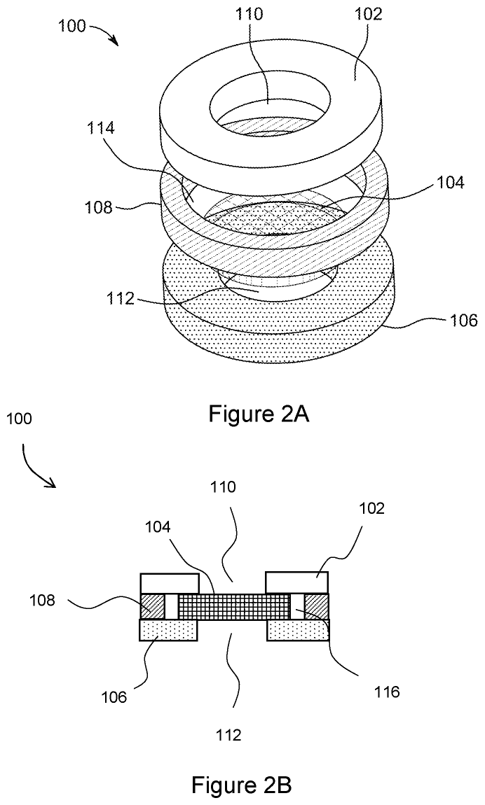

With reference to FIG. 2A and FIG. 2B a vent assembly 100 comprises a first adhesive layer 102 (acting as a first connecting layer), a mesh 104 (acting as a protective element), a second adhesive layer 106 (acting as a second connecting layer) and a spacer 108. The first adhesive layer 102 comprises a first aperture 110 and the second adhesive layer 106 comprises a second aperture 112. The first aperture 110 and the second aperture 112 form a through hole. The mesh 104 and spacer 108 are sandwiched between the first adhesive layer 102 and the second adhesive layer 106 such that it occludes the through hole. The spacer 108 comprises a spacer aperture 114 and the mesh 104 is positioned in the spacer aperture 114 and occludes the through hole. The mesh 104 is dimensioned such that the mesh 104 does not contact the spacer 108 and there is a gap 116 between the edge of the mesh 104 and the interior edge of the spacer 108.

The mesh 104 comprises PET fibers. The mesh 104 is 60 μm thick. The spacer 108 comprises PET and is 60 μm thick such that the spacer 108 and the mesh 104 have the same thickness.

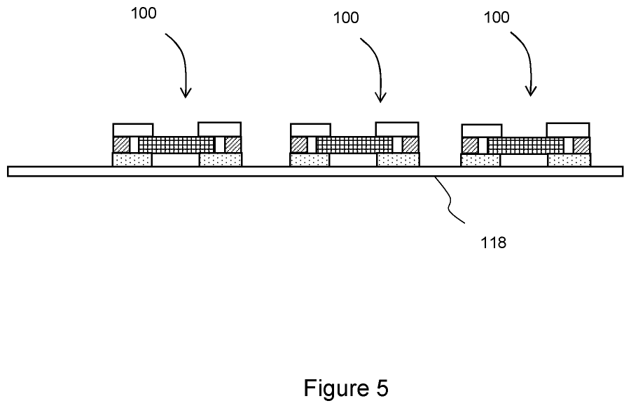

The vent assembly 100 is manufactured on a release paper 118 (see FIG. 5). The spacer 108 provides strength to the vent assembly so that they are much easier to handle and helps to prevent the vent assembly 100 becoming wrinkled or otherwise folded or bent when vent assembly 100 is removed from the release paper 118 and positioned onto an aperture 120 in a housing 122. The vent assembly 100 is then adhered to the housing 122 via the first adhesive layer 102.

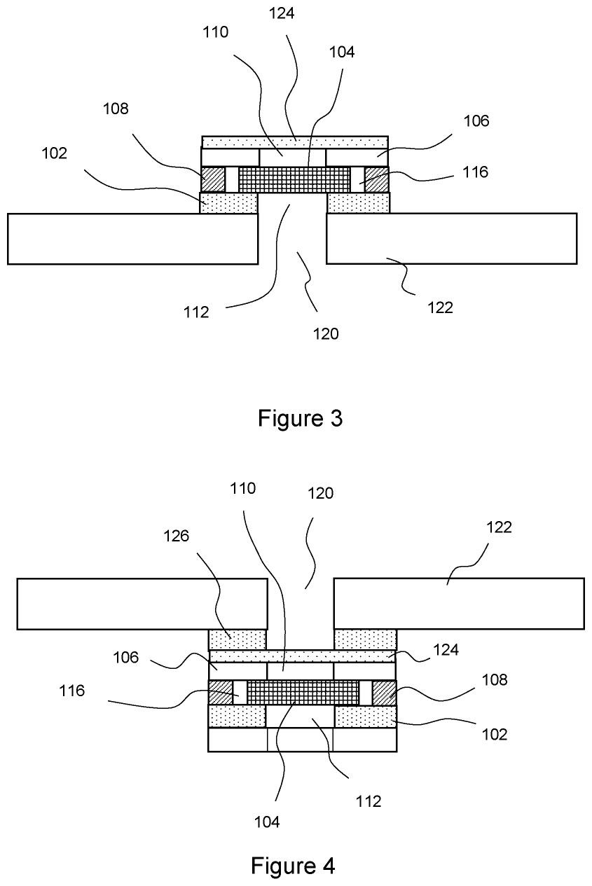

With reference to FIG. 3 the vent assembly 100 further comprises a membrane 124 adhered to the second adhesive layer 106 and the vent assembly 100 is positioned on the exterior of the housing 122. The membrane 124 faces the exterior of the housing 122.

### Example 2

In an alternative example with reference to FIG. 4, the vent assembly 100 is adhered to the housing 122 via a third adhesive layer 126 adhered to the membrane 124 and the vent assembly 100 is positioned within the housing 122 such that the membrane 124 faces the exterior of the housing 122.

### Example 3

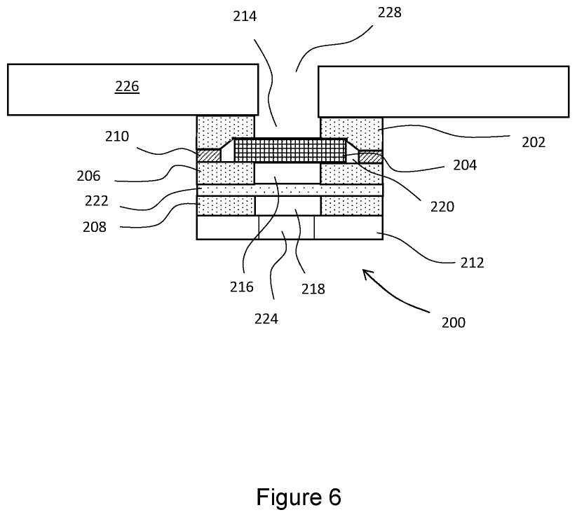

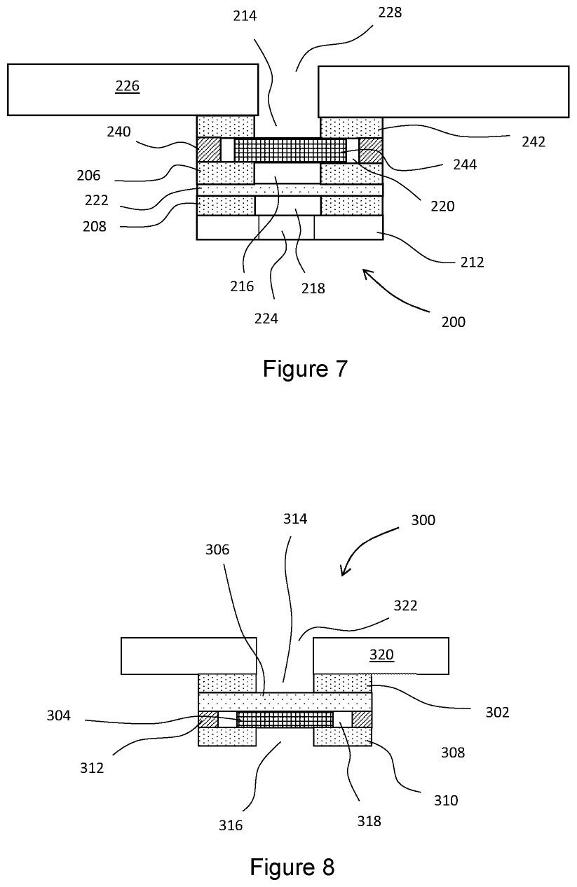

In a detailed example with reference to FIG. 6, a vent assembly 200 comprises a first connecting layer 202, a mesh 204 (acting as a protective element), a second connecting layer 206, a third connecting layer 208, a spacer 210 and a cover 212. The first connecting layer 202 comprises an acrylic foam that is compressible and a first aperture 214. The second connecting layer 206 comprises a second aperture 216. The third connecting layer 208 comprises a third aperture 218. The first aperture 214, the second aperture 216, and the third aperture 218 form a through hole. The mesh 204 and spacer 210 are sandwiched between the first connecting layer 202 and the second connecting layer 206 such that the mesh 204 occludes the through hole and the first connecting layer 202 compresses in contact with the mesh 204 and adheres to the mesh 204 and spacer 210. The spacer 210 comprises a spacer aperture 220 and the mesh 204 is positioned in the spacer aperture 220 and occludes the through hole. The mesh 204 is dimensioned such that the mesh 204 does not contact the spacer 210 and there is a gap between the edge of the mesh 204 and the interior edge of the spacer 210.

The mesh 204 comprises polyethylene terephthalate (PET) fiber and has a pore size of 18 μm.

The vent assembly 200 further comprises an expanded polytetrafluoroethylene (ePTFE) membrane 222 sandwiched between the second connecting layer 206 and the third connecting layer 208. The cover 212 comprises a polyurethane foam material on a PET film and is connected to the third connecting layer 208 and comprises a cover aperture 224 that is aligned with the through hole formed by the first aperture 214, the second aperture 216 and the third aperture 218.

The vent assembly 200 is connected to a housing 226 by the first connecting layer 202. The housing 226 comprises an aperture 228 and the vent assembly 200 is mounted to the housing 226 such that the through hole of the vent assembly 200 is aligned with the aperture 228 of the housing 226.

The first connecting layer 202, the second connecting layer 206 and the third connecting layer 208 comprise adhesive on both sides and the vent assembly 200 is connected together by adhering the components to one another where the components come into contact with one another.

The components of the vent assembly 200 are described in Table 1 below:

TABLE 1
Components of Venting Assembly of Example 3

| Component | Thickness | Material |
|---|---|---|
| First connecting layer | 250 μm | VHX-802 (3M) |
| Mesh | 60 μm | B260 (SAATI) |
| Spacer | 25 μm | polyethylene terephthalate |
| | | (PET) |
| Second connecting layer | 80 μm | FT8392 (Avery Dennison) |
| Membrane | 10 μm | GAW337 (W. L. Gore) |
| Third Connecting layer | 30 μm | #4983 (Tesa) |
| Cover | 200 μm | Poron SR-S-70P (Rogers |
| | | Inoac) |

The material (column 3) is given as the manufacturer part no. followed by manufacturer in brackets.

### Example 4

In a further alternative example, a vent assembly is provided according to Example 3 where the mesh has a thickness of 80 μm and the material was HD10BHY (SAATI).

### Example 5

In a further alternative example, a vent assembly is provided according to Example 3 where the spacer 240 is the same thickness as the mesh 244 and the first connecting layer 242 is substantially level.

### Example 6

In a further alternative example with reference to FIG. 8, a vent assembly 300 comprises a first connecting layer 302, a mesh 304 laminated to a membrane 306 forming a protective element 308, a second connecting layer 310, and a connecting spacer 312. The first connecting layer 302 comprises a first aperture 314. The second connecting layer 308 comprises a second aperture 316. The first aperture 314, and the second aperture 316 form a through hole. The protective element 308 and the connecting spacer 312 are sandwiched between the first connecting layer 302 and the second connecting layer 310 such that protective element 308 occludes the through hole. The connecting spacer 312 comprises a spacer aperture 318 and the mesh 304 is positioned in the spacer aperture 318 and occludes the through hole. The mesh 304 is dimensioned such that the mesh 304 does not contact the connecting spacer 312 and there is a gap between the edge of the mesh 304 and the interior edge of the connecting spacer 312.

The mesh 304 supports the membrane 306 and improves the physical resilience of the membrane 306.

The vent assembly 300 is connected to a housing 320 with the first connecting layer. The housing 320 comprises an aperture 322 and the vent assembly 300 is positioned over the aperture 322 such that the through hole of the vent assembly 300 is aligned with the aperture 322. The first connecting layer 302 connects the membrane 306 of the protective element 308 to the housing 320. The membrane 306 of the protective element 308 overhangs the mesh 304 and connects to the connecting spacer 312. The connecting spacer 312 connects to the second connecting layer 310 and the second connecting layer 310 is connected to the mesh 304 of the protective element 308.

### Comparative Example 2

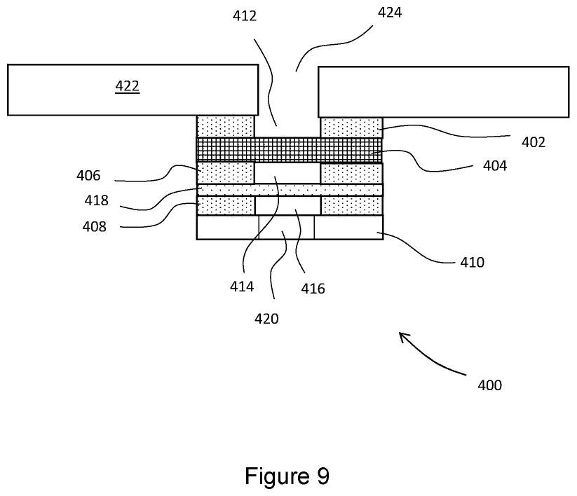

In a detailed comparative example with reference to FIG. 9, a vent assembly 400 comprises a first connecting layer 402, a mesh 404 (acting as a protective element), a second connecting layer 406, a third connecting layer 408, and a cover 410. The first connecting layer 402 comprises a first aperture 412. The second connecting layer 406 comprises a second aperture 414. The third connecting layer 408 comprises a third aperture 416. The first aperture 412, the second aperture 414, and the third aperture 416 form a through hole. The mesh 404 is sandwiched between the first connecting layer 402 and the second connecting layer 406 such that the mesh 404 occludes the through hole.

The mesh 404 comprises polyethylene terephthalate (PET) fiber and has a pore size of 18 μm.

The vent assembly 400 further comprises an expanded polytetrafluoroethylene (ePTFE) membrane 418 sandwiched between the second connecting layer 406 and the third connecting layer 408. The cover 410 comprises a polyurethane foam material on a PET film and is connected to the third connecting layer 408 and comprises a cover aperture 420 that is aligned with the through hole formed by the first aperture 412, the second aperture 414 and the third aperture 416.

The vent assembly 400 is connected to a housing 422 by the first connecting layer 402. The housing 422 comprises an aperture 424 and the vent assembly 400 is mounted to the housing 422 such that the through hole of the vent assembly 400 is aligned with the aperture 424 of the housing 422.

The first connecting layer 402, the second connecting layer 406 and the third connecting layer 408 comprise adhesive on both sides and the vent assembly 400 is connected together by adhering the components to one another where the components come into contact with one another.

The components of the vent assembly 400 are described in Table 2 below:

TABLE 2
Components of Venting Assembly of Comparative Example 2

| Component | Thickness | Material |
|---|---|---|
| First connecting layer | 250 μm | VHX-802 (3M) |
| Mesh | 60 μm | B260 (SAATI) |
| Second connecting layer | 80 μm | FT8392 (Avery Dennison) |
| Membrane | 10 μm | GAW337 (W. L. Gore) |
| Third Connecting layer | 30 μm | #4983 (Tesa) |
| Cover | 200 μm | Poron SR-S-70P (Rogers |
| | | Inoac) |

The material (column 3) is given as the manufacturer part no. followed by manufacturer in brackets.

### Test Methods

### Thickness Measurement

The thickness of the components of vent assemblies described above were measured using a conventional micrometer. Alternative methods may be used.

### Water Entry Pressure (WEP)

In order to assess the efficacy of the vent according to the disclosure, the water leakage through the vent was tested using a water entry pressure (WEP) test method.

The vent assemblies according to Example 3, Example 4 and Comparative Example 2 were subjected to water pressure of 15 kPa for a testing period of 30 minutes. After the testing period the vent is checked to determine whether water leakage has occurred. If any water was detected to have leaked through the vent the vent was determined to have failed the test.

Samples according to the Comparative Example 2 all were found to fail the WEP test indicating that the samples suffered from water leakage.

In contrast all samples according to Example 3 and Example 4 were found to pass the WEP test and none were found to suffer from leakage.

While there has been hereinbefore described approved embodiments of the present invention, it will be readily apparent that many and various changes and modifications in form, design, structure and arrangement of parts may be made for other embodiments without departing from the invention and it will be understood that all such changes and modifications are contemplated as embodiments as a part of the present invention as defined in the appended claims.

1. A vent assembly comprising a first connecting layer, a spacer, and a protective element, the first connecting layer comprises a first aperture, wherein the spacer comprises a spacer aperture and the protective element is located within the spacer aperture and occludes the first aperture, and wherein the spacer and protective element are contacted by the first connecting layer.

2. The vent assembly of claim 1, wherein the protective element comprises a mesh layer.

3. The vent assembly of claim 2, wherein the mesh layer comprises a weave of polymer fibers.

4. The vent assembly of claim 3, wherein the polymer fiber comprises polyethylene (PE), polyethylene terephthalate (PET), or a fluoropolymer including polytetrafluoroethylene (PTFE) or fluorinated ethylene propylene (FEP).

5. The vent assembly according to claim 1, wherein the protective element comprises a porous membrane.

6. The vent assembly according to claim 1, wherein the protective element comprises a water resistant coating.

7. The vent assembly according to claim 1, wherein the protective element has a thickness of from about 10 μm to about 200 μm.

8. The vent assembly according to claim 1, wherein the protective element is positioned substantially within the center of the spacer aperture.

9. The vent assembly according to claim 1, wherein the spacer comprises a water resistant polymer material.

10. The vent assembly according to claim 1, wherein the spacer has a thickness of from about 10 μm to about 200 μm.

11. The vent assembly according to claim 1, wherein the spacer and protective element are the same thickness or substantially the same thickness.

12. The vent assembly according to claim 1, wherein the vent assembly further comprises a second connecting layer.

13. The vent assembly according to claim 1, wherein the first connecting layer and, when dependent on claim 12, the second connecting layer are substantially planar across at least the spacer and the protective element.

14. The vent assembly according to claim 1, wherein the vent assembly further comprises a membrane connected to the first connecting layer.

15. An electronic device comprising a housing and vent assembly according to claim 1, wherein the housing comprises at least one aperture and the vent assembly covers the at least one aperture.

16. An electronic device according to claim 15, wherein the vent assembly is connected to the housing via the first connecting layer.
